(19) United States
(12) Patent Application Publication
(10) Pub. No.: US 2004/0053431 A1
(43) Pub. Date: Mar. 18, 2004

(54) Method of forming a flexible thin film transistor display device with a metal foil substrate

(75) Inventors: Chich Shang Chang, Taoyuan (TW); Wen-Tung Wang, Hsinchu (TW); Yuan-Tung Dai, Taoyuan (TW); Chiung-Wei Lin, Taipei (TW); Chi-Lin Chen, Hsinchu (TW); Tsung-Neng Liao, Taichung (TW); Chi-Shen Lee, Hsinchu (TW)

Correspondence Address: QUINTERO LAW OFFICE, 1617 BROADWAY, 3RD FLOOR, SANTA MONICA, CA, 90404, US

(73) Assignee: Industrial Technology Research Institute

(21) Appl. No.: 10/459,032

(22) Filed: Jun. 11, 2003

(30) Foreign Application Priority Data
Sep. 13, 2002 (TW) 91120975

(51) Int. Cl. H01L 21/00; H01L 21/84

(52) U.S. Cl. 438/30

(57) ABSTRACT

A method of forming a flexible thin film transistor (TFT) display device. A metal foil serving as a flexible metal substrate of a display device is provided, wherein the metal foil is an aluminum alloy foil, a titanium foil or a titanium alloy foil. The thickness of the metal foil is 0.05˜0.8 mm. An insulation layer is formed on the flexible metal substrate. A thin film transistor (TFT) array is formed on the insulation layer. In addition, the aluminum alloy foil can include magnesium of 0.01˜1% wt and/or silicon of 0.01˜1% wt and the titanium alloy foil can include aluminum of 0.01˜20% wt and/or molybdenum of 0.01˜20% wt.

### BACKGROUND OF THE INVENTION

1. Field of the Invention

The present invention relates to a flexible display process, and more particularly, to a method of forming a flexible thin film transistor (TFT) display with a metal foil substrate, such as an aluminum alloy foil, a titanium foil or a titanium alloy foil.

2. Description of the Related Art

Plastic displays with plastic substrates are attractive for use in flat panel displays because such displays are lightweight, flexible and unbreakable.

However, during the high temperature process of forming an active device such as a thin film transistor (TFT) directly on a plastic substrate, the plastic substrate which has a glass transition temperature of less than 200° C. is subject to dimensional instability. Moreover, because of the very large difference in thermal expansion coefficients between the plastic substrate and the TFT, the thin film of the TFT may separate or crack during the repeated thermal cycles required by the fabrication process and is thus detrimental to device reliability and yield.

Additionally, the plastic substrate is inadequately protected from chemicals, oxygen, moisture, mechanical impact, static electricity, and other damaging factors. As a result life span of plastic-based display devices is limited.

Recently, a stainless steel foil, serving as a flexible substrate display material, has been investigated. Stainless steel, however, with a density of about 7.9 g/cm³, has the disadvantage of being heavier than plastic and hinders the development of lightweight displays. Additionally, the higher thermal expansion coefficient (about 17.3E-6/° C.) of stainless steel may affect the deposition of a thin film transistor (TFT). Therefore, it is important to discover an optimal substrate material.

### SUMMARY OF THE INVENTION

The object of the present invention is to provide a method of forming a flexible thin film transistor display.

Another object of the present invention is to provide a method of forming a flexible thin film transistor display having a metal foil substrate, wherein the metal foil substrate is an aluminum alloy foil, a titanium foil or a titanium alloy foil.

In order to achieve these objects, the present invention provides a method of forming a flexible thin film transistor (TFT) display device. A metal foil serving as a flexible metal substrate of a display device is provided, wherein the metal foil is an aluminum alloy foil, a titanium foil or a titanium alloy foil. The thickness of the metal foil is 0.05˜0.8 mm. An insulation layer is formed on the flexible metal substrate. A thin film transistor (TFT) array is formed on the insulation layer. In addition, the aluminum alloy foil can include magnesium of 0.01˜1% wt and/or silicon of 0.01˜1% wt and the titanium alloy foil can include aluminum of 0.01˜20% wt and/or molybdenum of 0.01˜20% wt.

The present invention improves on the prior art in that it utilizes a metal foil, such as an aluminum alloy foil, a titanium foil or a titanium alloy foil, as a flexible substrate, and an insulation layer is then formed on the surface of the metal foil. Since aluminum alloy, titanium and titanium alloy have the properties of a high melting point (above 600° C.), low density, low thermal expansion coefficient, good flexibility, and high strength, aluminum alloy, titanium or titanium alloy foils are an optimal substrate material for flexible thin film transistor (TFT) display devices. Thus, the present invention is suitable for use in fabrication of flexible displays, such as flexible thin film transistor (TFT) displays.

### BRIEF DESCRIPTION OF THE DRAWINGS

The present invention can be more fully understood by reading the subsequent detailed description in conjunction with the examples and references made to the accompanying drawings, wherein:

FIGS. 1˜2 are sectional views according to an embodiment of the present invention.

FIG. 3 is a sectional view showing an application of the present invention to a flexible reflective liquid crystal display device; and

FIG. 4 is a sectional view showing another application of the present invention to a flexible organic electroluminescent display device.

### DETAILED DESCRIPTION OF THE INVENTION

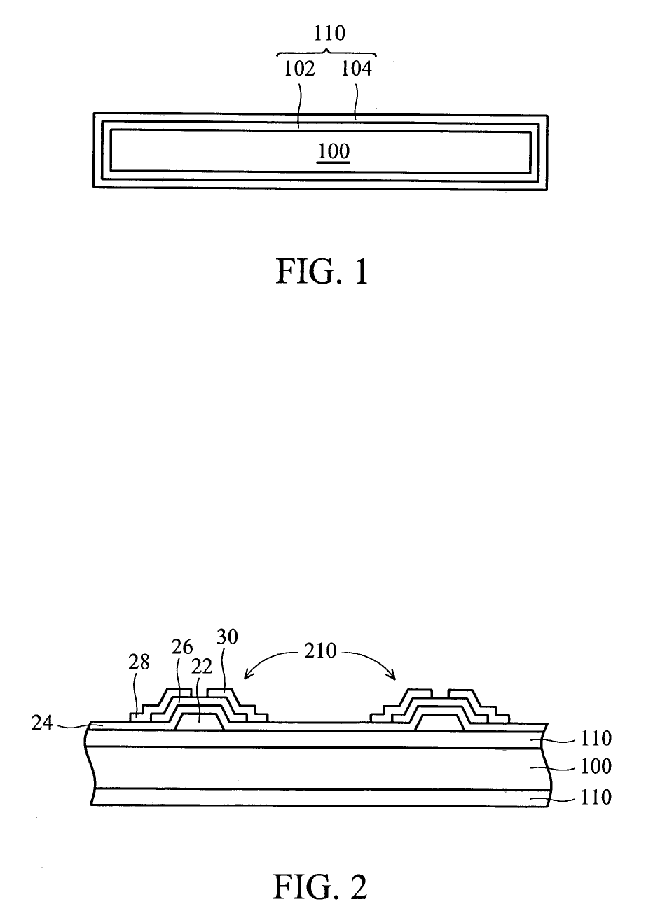

The present invention provides a method of forming a flexible thin film transistor (TFT) display device. FIGS. 1˜2 are schematic diagrams according to an embodiment of the present invention.

In FIG. 1, a metal foil 100 serving as a flexible metal substrate 100 of a display device, wherein the metal foil is an aluminum alloy (Al alloy) foil, a titanium (Ti) foil or a titanium alloy (Ti alloy) foil. The thickness of the metal foil 100 is about 0.05˜0.8 mm.

It should be noted that, when using the Al alloy foil as the flexible metal substrate 100, the Al alloy foil includes other beneficial elements, such as silicon (Si) and/or magnesium (Mg). For example, adding magnesium (Mg) can decrease the density of the Al alloy foil, thereby reducing weight. Adding silicon (Si) can reduce the thermal expansion coefficient of the Al alloy foil. Also, silicon (Si) can improve the mechanical property of the Al alloy foil, for example, enhancing strength, toughness and rigidity. The content of magnesium (Mg) in the Al alloy foil is preferably 0.01˜1% wt, and the content of silicon (Si) in the Al alloy foil is preferably 0.01˜1% wt.

Additionally, pure titanium (Ti) foil is also well suited to serve as the flexible metal substrate 100 in a thin film transistor (TFT) process because pure titanium (Ti) has a high melting point of about 1668° C., a low density of about 4.45 g/cm³, a low thermal expansion coefficient of about 8.4E-6/° C., and sufficient strength. Moreover, in order to enhance rigidity of the titanium (Ti) foil, a Ti alloy foil comprising aluminum of 0.01˜20% wt and/or molybdenum of 0.01˜20% wt can be utilized. Thus, the flexible metal substrate 100 comprising Al alloy foil, Ti foil, or Ti alloy foil is well suited for use in high temperature processes.

In FIG. 1, an insulation layer 110 with a thickness of about 500˜10000 angstroms is formed on the metal substrate 100. As a demonstrative method of forming the insulation layer 110 on the metal substrate 100, referring to FIG. 1, a metal oxide film 102 is formed on the surface of the metal substrate 100 by thermal oxidation. When the metal substrate 100 is an Al alloy foil, the metal oxide film 102 is an Al₂O₃ film. When the metal substrate 100 is a Ti foil or a Ti alloy foil, the metal oxide film 102 is a TiO₂ film.

In FIG. 1, using deposition, an insulating film 104 is formed on the metal oxide film 102 to improve the insulation property of the insulation layer 110. The insulating film 104 can be a SiO₂ layer, a TiO₂ layer or a SiNₓ layer. That is, the insulation layer 110 can be a stack structure.

In FIG. 2, a thin film transistor (TFT) array 210 is formed on the insulation layer 110. The TFT structure of the TFT array 210 can be a bottom gate type TFT or a top gate type TFT structure. In FIG. 2, the TFT array 210 with the bottom gate type TFT structure is shown, but is not intended to limit the invention. The bottom gate type TFT structure includes a gate electrode 22, a gate insulating layer 24, a semiconductor layer 26 and source/drain regions 28/30. In order to avoid obscuring aspects of the invention, the description of the known TFT process is omitted.

It should be noted that the aluminum alloy substrate, the titanium substrate, and the titanium alloy substrate of the present invention all have a high melting point of above 600° C., enabling their use in conventional high temperature TFT (e.g. a-Si TFT or LTPS TFT) processes of the invention. Thus, the present invention is well suited to the fabrication of flexible displays, such as flexible thin film transistor (TFT) displays.

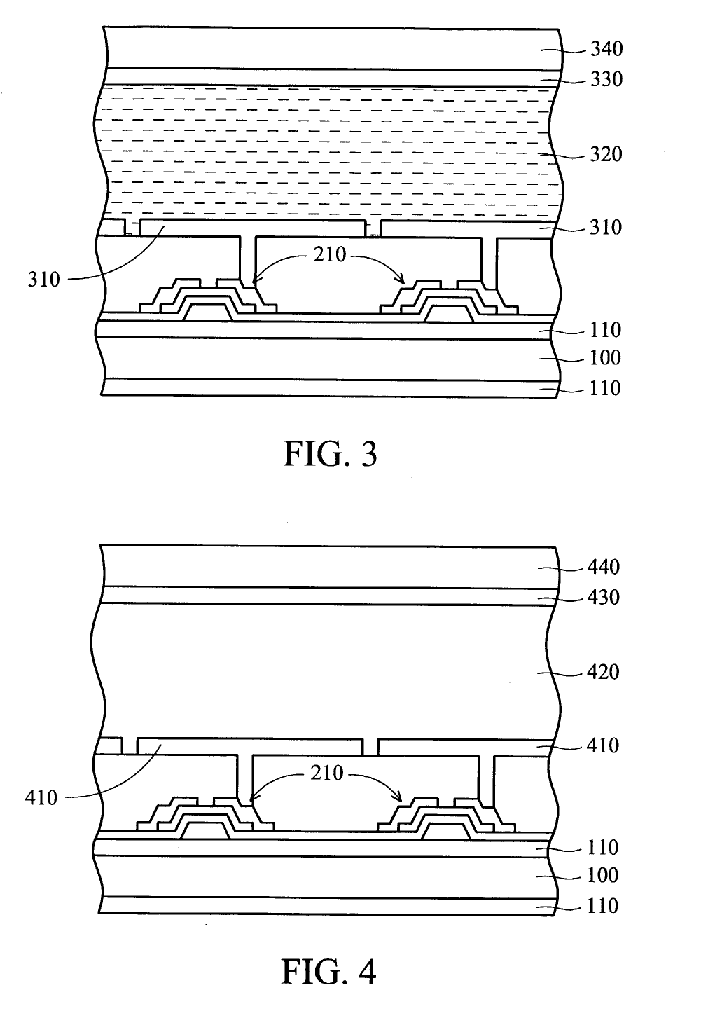

Hereinafter, a flexible reflective liquid crystal display device (RLCD) and a flexible organic electroluminescent display device (OELD) as demonstrative applications will be explained next with reference to FIGS. 3 and 4.

First Application

FIG. 3 is a sectional view showing an application of the present invention to a flexible reflective liquidcrystal display device.

In FIG. 3, a plurality of transparent pixel electrodes 310 are formed to electrically connect to the TFT array 210. The transparent pixel electrode 310 may be an indium tin oxide (ITO) or indium zinc oxide (IZO) layer formed by sputtering. Then, a common electrode 330 is formed on an inner side of a transparent plastic substrate 340 opposite the metal substrate 100. The transparent plastic substrate 340 serves as an upper substrate. The common electrode 330 may be an indium tin oxide (ITO) or indium zinc oxide (IZO) layer formed by sputtering. A display material, such as liquid crystal molecules, is then filled in a space between the metal substrate 100 and the transparent plastic substrate 340 to form a display layer 420.

It should be noted that the above mentioned liquid crystal material can comprise other display materials, such as, microcapsules with an electrophoretic characteristic.

Second Application

FIG. 4 is a sectional view showing another application of the present invention to a flexible organic electroluminescent display device.

In FIG. 4, a plurality of anode electrodes 410 are formed to electrically connect to the TFT array 210. The anode electrode 410 may be an indium tin oxide (ITO) electrode. Then, an emitter layer such as an organic electroluminescent layer 420 is formed on the anode electrodes 410 by, for example, evaporation. The organic electroluminescent layer 420 includes low polymer or high polymer material. A cathode electrode 430 is then formed on the organic electroluminescent layer 420. The cathode electrode 430 may be a metal electrode. Finally, a transparent plastic substrate 440 is disposed on the cathode electrode 330.

Thus, the present invention produces a novel flexible TFT display device using the metal foil, such as the aluminum alloy foil, the titanium foil or the titanium alloy foil, as a substrate. Also, since the melting point of the metal foils is above 600° C. and the thermal expansion coefficient of the metal foils is lower than conventional plastic plates, the metal foils are well suited for use in current equipment employing high temperature TFT processes, thereby improving device reliability and yield and ameliorating the disadvantages of the prior art. In addition, aluminum alloy, titanium, and titanium alloy foils are less expensive and thereby reduce manufacturing cost.

Finally, while the invention has been described by way of example and in terms of the above, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A method of forming a flexible thin film transistor (TFT) display device, comprising the steps of:
providing a metal foil serving as a flexible metal substrate of a display device, wherein the metal foil is an aluminum alloy foil, a titanium foil or a titanium alloy foil;
forming an insulation layer on the flexible metal substrate; and
forming a thin film transistor (TFT) array on the insulation layer.

2. The method according to claim 1, wherein the aluminum alloy foil comprises silicon.

3. The method according to claim 1, wherein the aluminum alloy foil comprises magnesium.

4. The method according to claim 3, wherein the titanium alloy foil comprises aluminum.

5. The method according to claim 1, wherein the titanium alloy foil comprises molybdenum.

6. The method according to claim 1, wherein a thickness of the metal foil is about 0.05˜0.8 mm.

7. The method according to claim 1, wherein a method of forming the insulation layer on the metal substrate comprises the steps of:
forming a metal oxide film on the metal substrate; and
forming an insulating film on the metal oxide film.

8. The method according to claim 7, wherein the metal oxide film is an Al₂O₃ film or a TiO₂ film formed by thermal oxidation.

9. The method according to claim 7, wherein the insulation film is a SiO₂ layer, a TiO₂ layer or a SiNₓ layer formed by deposition.

10. The method according to claim 1, further comprising the steps of:
forming a plurality of transparent pixel electrodes electrically connected to the TFT array;
providing a transparent plastic substrate opposite the metal substrate;
forming a common electrode on an inner side of the transparent plastic substrate; and
forming a display layer between the metal substrate and the transparent plastic substrate.

11. The method according to claim 10, wherein the display layer is a liquid crystal layer.

12. The method according to claim 1, further comprising the steps of:
forming a plurality of anode electrodes electrically connected to the TFT array;
forming an organic electroluminescent layer on the anode electrodes;
forming a cathode electrode on the organic electroluminescent layer; and
forming a transparent plastic substrate on the cathode electrode.

13. The method according to claim 12, wherein the organic electroluminescent layer comprises low polymer or high polymer material.

14. A method of forming a flexible thin film transistor (TFT) display device, comprising the steps of:
providing an aluminum alloy foil serving as a flexible metal substrate of a display device, wherein the aluminum alloy foil comprises magnesium of 0.01˜1% wt and/or silicon of 0.01˜1% wt;
forming an insulation layer on the flexible metal substrate; and
forming a thin film transistor (TFT) array on the insulation layer.

15. The method according to claim 14, wherein a thickness of the aluminum alloy foil is about 0.05˜0.8 mm.

16. A method of forming a flexible thin film transistor (TFT) display device, comprising the steps of:
providing an titanium alloy foil serving as a flexible metal substrate of a display device, wherein the titanium alloy foil comprises aluminum of 0.01˜20% wt and/or molybdenum of 0.01˜20% wt;
forming an insulation layer on the flexible metal substrate; and
forming a thin film transistor (TFT) array on the insulation layer.

17. The method according to claim 16, wherein a thickness of the titanium alloy foil is about 0.05˜0.8 mm.
